(19) United States
(12) Patent Application Publication
(10) Pub. No.: US 2006/0093855 A1
(43) Pub. Date: May 4, 2006

(54) Organometallic compounds and display device employing the same

(75) Inventor: Pei-Chi Wu, Kaohsiung City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/099,108

(22) Filed: Apr. 5, 2005

(30) Foreign Application Priority Data
Nov. 4, 2004 (TW) 93133589

(51) Int. Cl. C09K 11/06; H01L 51/54; H05B 33/14

(52) U.S. Cl. 428/690; 428/917; 313/504; 546/4; 546/10; 252/301.16; 257/E51.044

(57) ABSTRACT

An organometallic complex has formula (I) 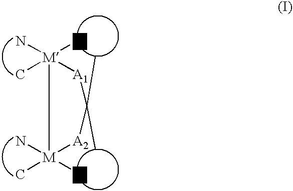
wherein M and M′ can be each independently transition metals; R can be a heterocyclic group including at least one nitride atom; A1 and A2 can be each independently a sulfur, oxygen, or nitride atom; and 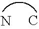 are independently a bidentate ligand comprising a nitride atom and a carbon atom bonded to M or M′

### BACKGROUND

The invention relates to an organometallic compound and, more particularly, to an organometallic compound serving as electroluminescent material for an organic electroluminescent display device.

Recently, with the development and wide application of electronic products, such as mobile phones, PDAs, and notebook computers, there has been increasing demand for flat display elements which consume less electric power and occupy less space. Organic electroluminescent devices are self-emitting and highly luminous, with wider viewing angle, faster response speed, and simpler fabrication, making them the industry display of choice.

Generally, an OLED is composed of a light-emitting layer sandwiched between a pair of electrodes. When an electric field is applied to the electrodes, the cathode injects electrons into the light-emitting layer and the anode injects holes into the light-emitting layer. When the electrons recombine with the holes in the light-emitting layer and excitons are formed. The recombination of electron and hole results in emission.

Depending on the spin states of the hole and electron, the exciton which results from hole and electron recombination can have either a triplet or singlet spin state. Luminescence from a singlet exciton results in fluorescence whereas luminescence from a triplet exciton results in phosphorescence. The emissive efficiency of phosphorescence is three times that of fluorescence. Therefore, it is crucial to develop highly efficient phosphorescent material, in order to increase the emissive efficiency of the OLED.

Certain organometallic complexes have been reported as having intense phosphorescence (Lamansky, et al., Inorganic Chemistry, 2001, 40, 1704), and efficient OLEDs emitting in the green to red spectrum have been prepared with these complexes (Lamansky, et al., J. Am. Chem. Soc., 2001, 123, 4304). U.S. Patent Application Publication 2002/0182441 discloses a phosphorescent organometallic complex emitting in the blue spectrum. U.S. Patent Application Publication 2003/0072964A1 discloses a phosphorescent organometallic complex including phenylquinolinato ligands.

U.S. Pat. No. 6,687,266 discloses a compound used as light-emitting layer material having the structure:

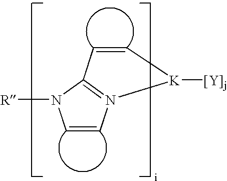

wherein K is Ir or Pt, R″ is alkyl group, Y is acetylacetonate, picolinate, or dipivaloylmetanate, and i and j are integers of 0 to 6, respectively.

U.S. Pat. No. 6,303,238 discloses a heteroatom-containing electroluminescent material comprising platinum octaethylporphine. U.S. Pat. No. 6,653,654 discloses a compound comprising a Group IIB transition metal and quadridentate ONNO-type ligands.

These and other conventionally used phosphorescent compounds are constructed from a single d⁶ transition metal such as Pt, Os, Ir, Re, or Ru, and exhibit low electroluminescent luminescent efficiency when used in organic electroluminescent devices. Further improvements in phosphorescent compounds serving as emitting layer material are desirable in a variety of flat panel display applications.

### SUMMARY

The invention provides an organometallic compound, prepared from a complex comprising dual transition metals reacting with pyridine-2-thiol or pyrimidine-2-thiol, represented by formula (I):

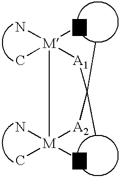

Accordingly, M and M′ can be each independently transition metals; R can be a heterocyclic group including at least one nitride atom; A₁ and A₂ can be each independently a sulfur, oxygen, or nitride atom; and 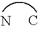
are independently a bidentate ligand comprising a nitride atom and a carbon atom bonded to M or M′.

Further provided is a display device, such as organic electroluminescent device, comprising an anode, a cathode, and organic electroluminescent layers therebetween, wherein the electroluminescent layers comprise the organometallic compound according to formula (I).

A detailed description is given in the following with reference to the accompanying drawing.

### BRIEF DESCRIPTION OF THE DRAWINGS

The invention can be more fully understood by reading the subsequent detailed description in conjunction with the examples and references made to the accompanying drawings, wherein:

FIG. 1 is a photoluminescence spectrum plotting wavelengths against intensity of embodiments of complex (I) and (II).

FIG. 2 is a photoluminescence spectrum plotting wavelengths against intensity of embodiments of complex (III) and (IV).

FIG. 3 is a photoluminescence spectrum plotting wavelengths against intensity of embodiments of complex (V).

FIG. 4 is an Oak Ridge Thermal Ellipsoid Program (ORTEP) diagram by X-ray single-crystal diffraction of embodiments of complex (I).

FIG. 5 is an ORTEP diagram by X-ray single-crystal diffraction of embodiments of complex (III).

### DETAILED DESCRIPTION

The present invention provides an organometallic complex containing two transition metals bonded together, bidentate ligands, and pyridine or pyrimidine groups containing sulfur or oxygen, having formula (I)

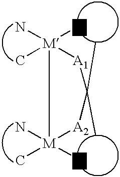

wherein,

R can be a heterocyclic group including at least one nitride atom;

A₁ and A₂ can be each independently a sulfur, oxygen, or nitride; 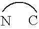
are independently a bidentate ligand comprising a nitride atom and a carbon atom bonded to M or M′. Representative examples include, but are not limited to, 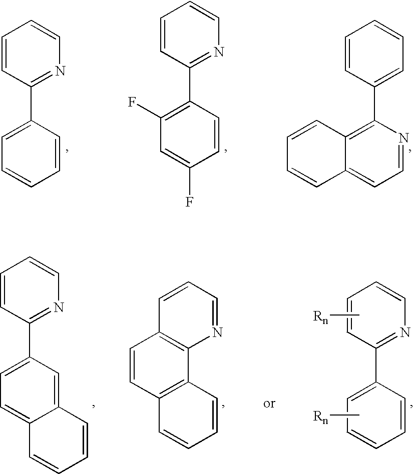
wherein Rn is hydrogen, alkyl, alkenyl, alkynyl, CN, CF₃, alkylamino, amino, alkoxy, halo, aryl, or heteroaryl, and at least one hydrogen atom bonded to the carbon atom of 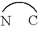
can be substituted optionally by electron donating or electron withdrawing groups, such as alkyl, alkenyl, alkynyl, CN, CF₃, alkylamino, amino, alkoxy, halo, aryl, or heteroaryl.

M and M′ can be each independently transition metals, preferably d⁶ transition metals with molecular weight more than 40, such as Ir, Os, Pt, Pb, Re, or Ru. Furthermore, M and M′ must be bonded each other.

The organometallic complex represented by formula (I), having advantages of easy preparation, high thermal stability, and high air-resistance, is natural, and exhibits photoluminescent and electroluminescent properties. Organic electroluminescent devices employing the organometallic compounds, acting as host materials, emit light in the orange or red spectrum.

None of the prior or related references disclose emitting layer materials comprising two transition metals bonded together. In the invention, the organometallic complexes exhibit superior physical and electroluminescent properties, when M and M′ both are platinum (II). Due to the special chemical configuration and strong metal bond of the organometallic compounds, organic electroluminescent devices employing the same exhibit high luminescent efficiency under bias voltage and great red color purity.

Furthermore, the organometallic compounds can also serve as phosphorescent dopant material for organic electroluminescent devices.

The following examples are intended to illustrate the invention more fully without limiting their scope, since numerous modifications and variations will be apparent to those skilled in the art.

Preparation of Organometallic Compounds

The following discloses the compound structures, and symbols for the compounds in the invention for better understanding.

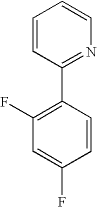

46dfppy: 2-(2,4-difluoro-phenyl)-pyridine

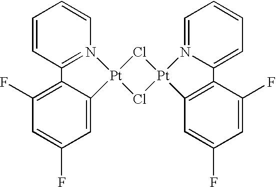

T1: (46dfppy) Pt (μ-Cl)₂Pt (46dfppy)

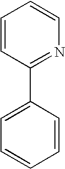

ppy: phenylpyridyl

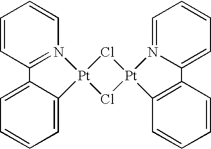

T2: (ppy) Pt (μ-Cl)₂Pt (ppy)

Preparation 1

46dfppy synthesis:

The synthesis pathway is as follows.

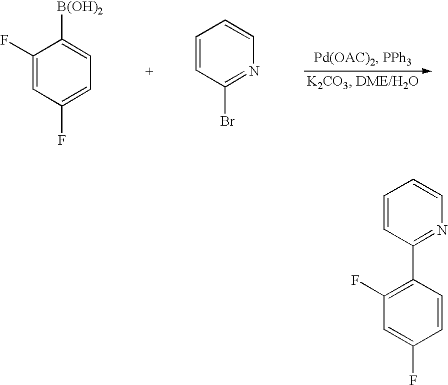

1.0 g of 2,4-difluorophenyl boronic acid (6.3 mmol), 0.036 g of Pd(acetate)2 (0.16 mmol), and 0.168 g triphenylphosphine (0.641 mmol) was dissolved in 12 ml K2CO3/H2O solution (2M) and 6 ml 1,2-dimethoxyethane. Then, the mixture was added dropwise 0.6 ml of 2-bromopyridine (6.33 mmol). After heating to ref lux for 24 hours and cooling to room temperature, the result was condensed in vacuum, yielding a brown solid. The solid product was dissolved in 60 ml of H2O and subjected to extraction with CH2Cl2. After filtration, condensation, and recrystallization from acetone/hexane, 2-(2,4-difluoro-phenyl)-pyridine was obtained in a 36% yield (0.43 g, 2.25 mmol) as a yellow crystal.

The analysis data: FAB-MS: m/e=191 (M+).

### Preparation 2

T1 synthesis:

The synthesis pathway is as follows.

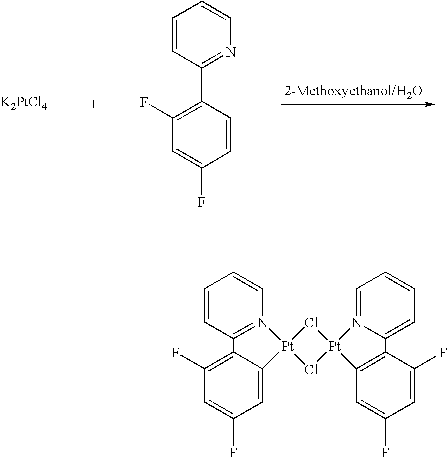

0.54 g of potassium tetrachloroplatinate(II) (1.3 mmol), and 0.52 g of 2-(2,4-difluoro-phenyl)-pyridine (2.73 mmol) was dissolved in a mixed solvent (2-methoxyethanol:H₂O=3:1). After heating to reflux for 24 hours, 20 ml of H₂O was added to the mixture for quenching. After filtering and washing with H2O/hexene, 0.89 g of compound T1 was obtained in a 82% yield.

Preparation 3

T2 synthesis:

The synthesis pathway is as follows.

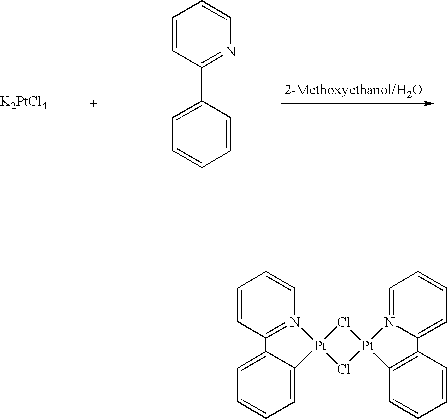

1 g of potassium tetrachloroplatinate(II) (2.41 mmol), and 1.12 g of phenylpyridyl (7.23 mmol) was dissolved in a mixed solvent (2-methoxyethanol:H2O=3:1). After heating to reflux for 24 hours, 20 ml of H2O was added to the mixture for quenching. After filtering and washing with H₂O/hexene, 1.57 g of compound T2 was obtained in a 85% yield.

### Example 1

Complex (I) synthesis:

The synthesis pathway is as follows.

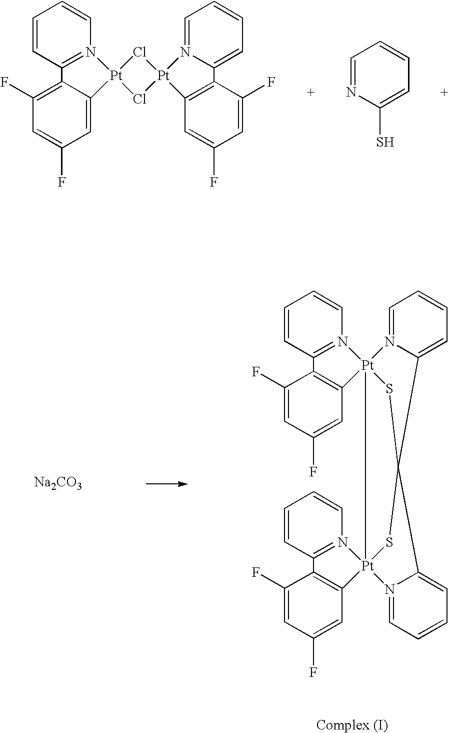

2.5 g of compound T1 (2.97 mmol), 0.76 g of pyridine-2-thiol (6.83 mmol), and 3.14 g of Na2CO3 (29.7 mmol) was dissolved in 2-methoxyethanol as solvent. After heating to reflux for 5 hours, 20 ml of H₂O was added to the mixture for quenching, and the solid was collected by filtration, and washed with D.I. water several times, giving 0.88 g of Complex (I) as a red solid. The final product was purified by vacuum sublimation (<3×10⁻⁴ torr, 270° C.), and the yield is 30%.

### Example 2

Complex (II) synthesis:

The synthesis pathway is as follows.

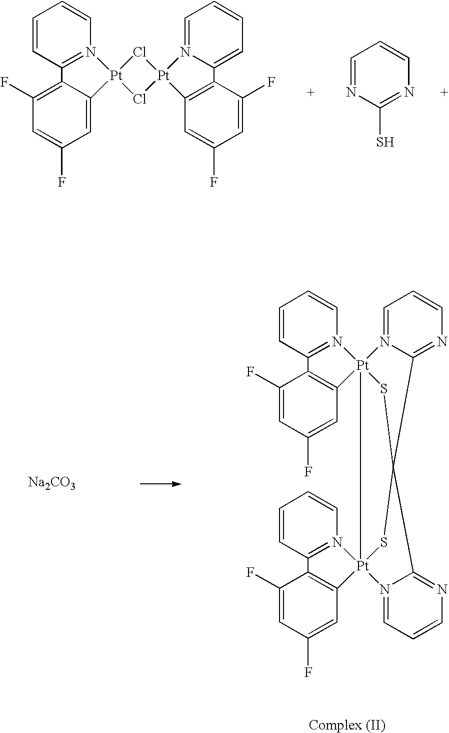

2.5 g of compound T1 (2.97 mmol), 0.77 g of pyrimidine-2-thiol (6.83 mmol), and 3.14 g of Na₂CO₃ (29.7 mmol) was dissolved in 2-methoxyethanol as solvent. After heating to reflux for 5 hours, 20 ml of H₂O was added to the mixture for quenching, and the solid was collected by filtration, and washed with D.I. water several times, giving 0.97 g of Complex (II). The final product was purified by vacuum sublimation (<3×10⁻⁴ torr, 270° C.), and the yield is 33%.

### Example 3

Complex (III) synthesis:

The synthesis pathway is as follows.

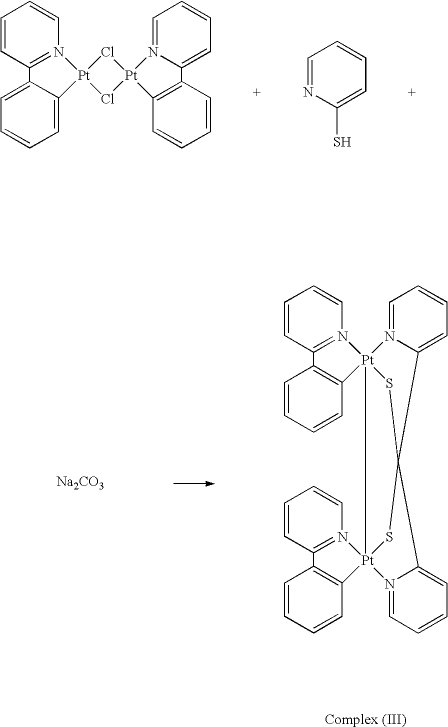

2.5 g of compound T2 (3.25 mmol), 0.83 g of pyridine-2-thiol (7.47 mmol), and 3.44 g of Na₂CO₃ (32.5 mmol) was dissolved in 2-methoxyethanol as solvent. After heating to reflux for 5 hours, 20 ml of H₂O was added to the mixture for quenching, and the solid was collected by filtration, and washed with D.I. water several times, giving 1.05 g of Complex (III) as a crystal. The final product was purified by vacuum sublimation (<3×10⁻⁴ torr, 270° C.), and the yield is 35%.

### Example 4

Complex (IV) synthesis:

The synthesis pathway is as follows.

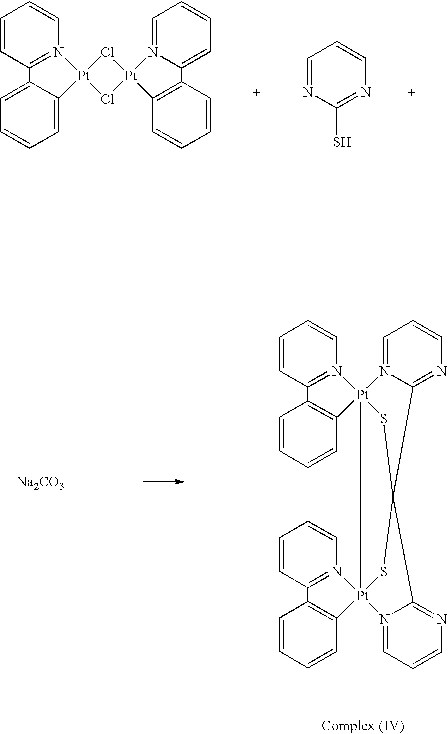

2.5 g of compound T2 (3.25 mmol), 0.71 g of pyrimidine-2-thiol (7.47 mmol), and 3.44 g of Na₂CO₃ (32.5 mmol) was dissolved in 2-methoxyethanol as solvent. After heating to reflux for 16 hours, 20 ml of H₂O was added to the mixture for quenching, and the solid was collected by filtration, and washed with H₂O/hexane several times, giving 1.20 g of Complex (II). The final product was purified by vacuum sublimation (<3×10⁻⁴ torr, 285° C.), and the yield is 40%.

### Example 5

Complex (V) synthesis:

The synthesis pathway is as follows.

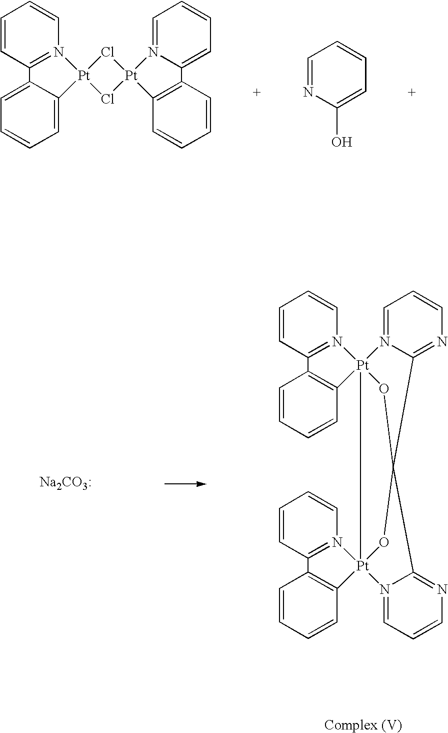

2.5 g of compound T2 (3.25 mmol), 0.71 g of pyridine-2-ol (7.47 mmol), and 3.44 g of Na₂CO₃ (32.5 mmol) was dissolved in 2-methoxyethanol as solvent. After heating to reflux for 5 hours, 20 ml of H₂O was added to the mixture for quenching, and the solid was collected by filtration, and washed with D.I. water several times, giving 0.87 g of Complex (II). The final product was purified by vacuum sublimation (<3×10⁻⁴ torr, 285° C.), and the yield is 30%.

The measured results of properties for Complexes (I)˜(V), as described in examples 1˜5, are shown in the following.

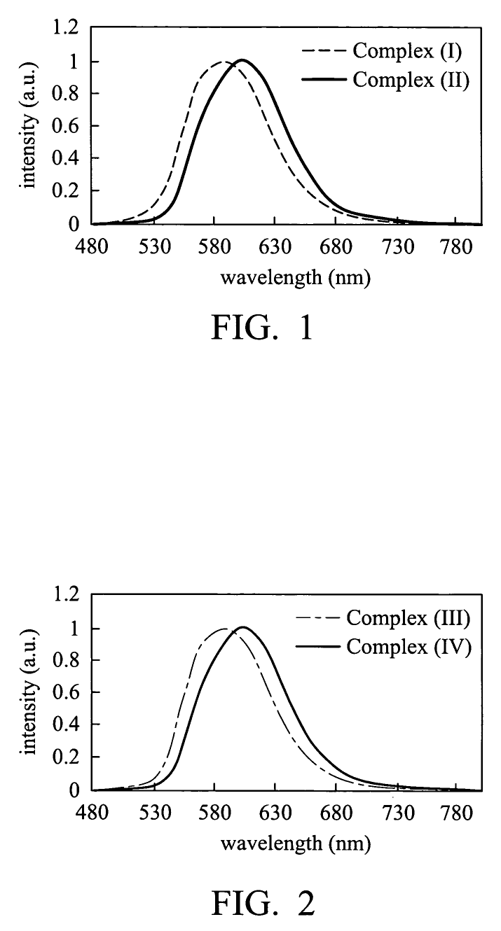

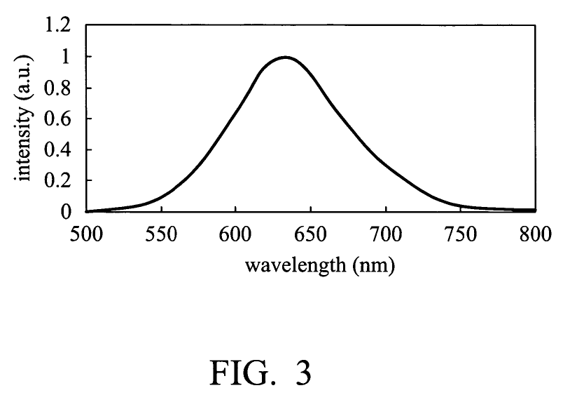

FIGS. 1˜3 illustrate the photoluminescent spectrums of Complexes (I)˜(V). It can be seen from the spectrums that the light emission maximum wavelengths of Complex (I)˜(V) are respectively 602 nm, 588 nm, 615 nm, 596 nm and 635 nm. Accordingly, the organometallic compounds of the invention can emit light in the orange or red spectrum, as shown in Table 1

Complexes (I)˜(V) were dispersed in CH₂Cl₂ and measured by RIKEN photoelectron spectrometer (type: RIKEN KEIKI) on AC-2 instruction, and the HOMO energy gaps of Complexes (I)˜(V) are respectively 5.2 eV, 5.16 eV, 5.25 eV, 5.19 eV and 5.22 eV, as shown in Table 1.

TABLE 1

| | maximum wavelength | HOMO energy gap |
|---|---|---|
| | (nm) | (eV) |
| Complex (I) | 602 | 5.2 |
| Complex (II) | 588 | 5.16 |
| Complex (III) | 615 | 5.25 |
| Complex (IV) | 596 | 5.19 |
| Complex (v) | 635 | 5.22 |

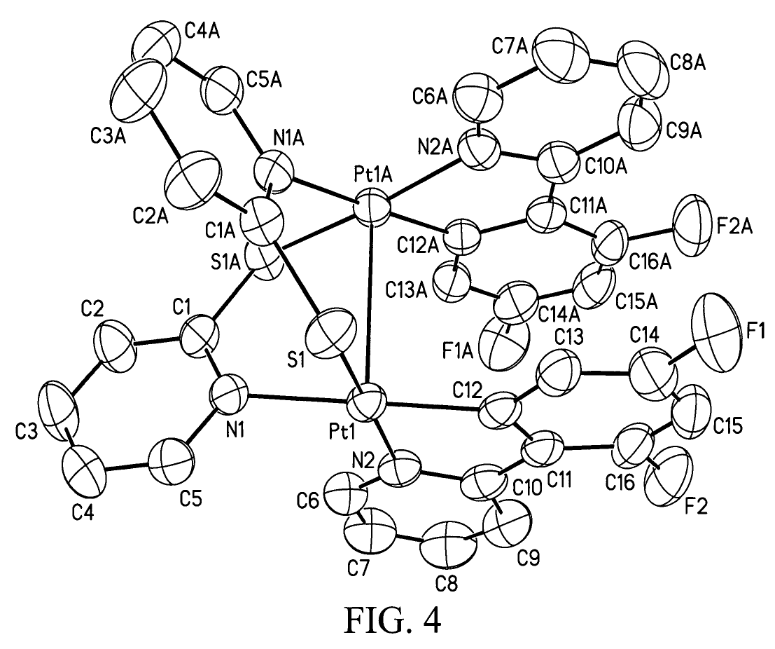

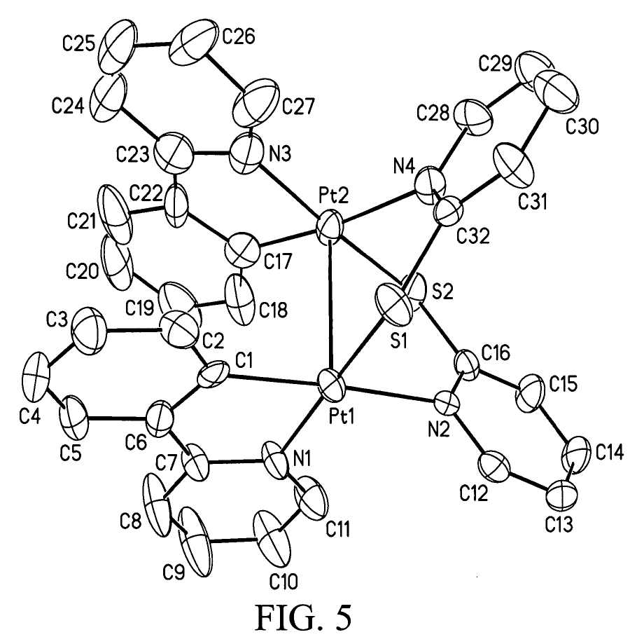

Complexes (I) and (III) are characterized by x-ray single-crystal diffractometer, and the X-ray crystal structure ORTEP diagram at the 30% probability level thereof are shown in FIGS. 4 and 5 and the x-ray crystallographic data are shown in Tables 2 and 3. Accordingly, each of Complexes (I) and (III) has two bonded transition metals, and the bond length of Pt-Pt bond are 2.8669 Å and 2.8552 Å respectively. Referring to FIGS. 4 and 5, the two transition metals of organometallic compounds and atom bonded therewith construct a five-member ring (Pt1-S1-C1A-N1A-Pt1A and Pt1-S1-C32-N4-Pt2). In comparison with conventional Pt complexes having a four-member ring, the organometallic compounds of the invention are more sublimable due to their three-dimensional configuration.

TABLE 2
crystallographic data of Complex (I)

| | |
|---|---|
| empirical formula | C₁₆H₁₀F₂N₂PtS |
| formula weight | 495.41 |
| temperature | 294(2) K |
| wavelength | 0.71073 Å |
| crystal system | Monoclinic |
| space group | C2/c |
| unit cell dimension | a = 21.889(3) Å α = 90° |
| | b = 11.7340(17) Å β = 23.962(2)° |
| | c = 13.609(2) Å γ = 90° |
| volume | 2899.1(7) Å³ |
| Z | 8 |
| density | 2.270 Mg/m³ |
| absorption coefficient | 9.842 mm⁻¹ |
| F(000) | 1856 |
| crystal size | 0.30 × 0.10 × 0.10 mm³ |
| theta. range for data | 2.07 to 28.30° |
| collection | |
| limiting indices | −29 ≦ h ≦ 28, −15 ≦ k ≦ 15, |
| | −16 ≦ l ≦ 18 |
| reflections collected | 9514 |
| independent reflections | 3494 [R(int) = 0.0428] |
| completion ratio | 96.8% |
| Max. & MIn. of absorption | 0.99024 and 0.40260 |
| data/restraints/Parameter | 3494/0/199 |
| Goodness-of-fit on F² | 1.171 |
| Final R, Rw[1 > 2s(1)] | R1 = 0.0339, wR2 = 0.0791 |
| R | R1 = 0.0393, wR2 = 0.0812 |
| LarDiff. Peak | 1.258 and −1.461 e.Å⁻³ |

bond angles (°) and distances (Å)

| | | | |
|---|---|---|---|
| Pt(1)—C(12) | 1.984(6) | N(2)—Pt(1)—N(1) | 94.32(18) |
| Pt(1)—N(2) | 2.044(5) | C(12)—Pt(1)—S(1) | 95.84(16) |
| Pt(1)—N(1) | 2.137(5) | N(2)—Pt(1)—S(1) | 173.84(13) |
| Pt(1)—S(1) | 2.2933(15) | N(1)—Pt(1)—S(1) | 88.96(13) |
| Pt(1)—Pt(1)#1 | 2.8669(6) | C(12)—Pt(1)—Pt(1)#1 | 94.07(15) |
| S(1)—C(1)#1 | 1.745(6) | N(2)—Pt(1)—Pt(1)#1 | 100.34(13) |
| F(1)—C(14) | 1.359(8) | N(1)—Pt(1)—Pt(1)#1 | 84.72(13) |
| F(2)—C(16) | 1.358(8) | S(1)—Pt(1)—Pt(1)#1 | 85.13(4) |
| N(1)—C(5) | 1.355(8) | C(1)#1—S(1)—Pt(1) | 107.6(2) |
| N(1)—C(1) | 1.361(7) | C(5)—N(1)—C(1) | 119.2(5) |
| N(2)—C(6) | 1.338(8) | C(5)—N(1)—Pt(1) | 115.9(4) |
| N(2)—C(10) | 1.364(8) | C(1)—N(1)—Pt(1) | 124.8(4) |
| C(1)—S(1)#1 | 1.745(6) | C(6)—N(2)—C(10) | 119.2(5) |
| C(2)—H(2A) | 0.9300 | C(6)—N(2)—Pt(1) | 124.8(4) |
| C(12)—Pt(1)—N(2) | 81.0(2) | C(10)—N(2)—Pt(1) | 116.0(4) |
| C(12)—Pt(1)—N(1) | 174.9(2) | | |

TABLE 3
crystallographic data of Complex (III)

| | |
|---|---|
| empirical formula | C₃₂ H₂₄ N₄ Pt₂ S₂ |
| formula weight | 918.85 |
| temperature | 298(2) K |
| wavelength | 0.71073 Å |
| crystal system | Monoclinic |
| space group | P2(1)/n |
| unit cell dimension | a = 12.5865(10) Å |
| | α = 90° |
| | b = 16.6141(14) Å |
| | β = 108.274(2)° |
| | c = 14.5284(12) Å |
| | γ = 90° |
| volume | 2884.9(4) Å³ |
| Z | 4 |
| density | 2.116 Mg/m³ |
| absorption coefficient | 9.862 mm⁻¹ |
| F(000) | 1728 |
| crystal size | 0.20 × 0.10 × 0.10 mm³ |
| theta. range for data | 1.87 to 25.72°. |
| collection | |
| limiting indices | −15 ≦ h ≦ 14, −20 ≦ k ≦ 18, |
| | −10 ≦ l ≦ 17 |
| reflections collected | 16080 |
| independent reflections | 5485 [R(int) = 0.0890] |
| completion ratio | 99.7% |
| Max. & MIn. of absorption | 0.93982 [symbol] 0.51957 |
| data/restraints/Parameter | 5485/0/361 |
| Goodness-of-fit on F² | 0.865 |
| Final R, Rw[1 > 2s(1)] | R1 = 0.0470, wR2 = 0.0666 |
| R | R1 = 0.1192, wR2 = 0.0791 |
| LarDiff. Peak | 1.462 and −1.081 e.Å⁻³ |

bond angles (°) and distances (Å)

| | | | |
|---|---|---|---|
| Pt(1)—C(1) | 2.019(10) | C(1)—Pt(1)—N(1) | 81.5(4) |
| Pt(1)—N(1) | 2.062(8) | C(1)—Pt(1)—N(2) | 175.4(4) |
| Pt(1)—N(2) | 2.144(7) | N(1)—Pt(1)—N(2) | 93.9(3) |
| Pt(1)—S(1) | 2.292(3) | C(1)—Pt(1)—S(1) | 94.6(3) |
| Pt(1)—Pt(2) | 2.8552(6) | N(1)—Pt(1)—S(1) | 173.4(2) |
| Pt(2)—C(17) | 1.935(15) | N(2)—Pt(1)—S(1) | 90.0(2) |
| Pt(2)—N(3) | 2.022(11) | C(1)—Pt(1)—Pt(2) | 95.2(3) |
| Pt(2)—N(4) | 2.153(8) | N(1)—Pt(1)—Pt(2) | 99.1(2) |
| Pt(2)—S(2) | 2.278(3) | N(2)—Pt(1)—Pt(2) | 85.5(2) |
| S(1)—C(32) | 1.749(10) | S(1)—Pt(1)—Pt(2) | 86.63(8) |
| S(2)—C(16) | 1.720(10) | C(17)—Pt(2)—N(3) | 80.0(5) |
| N(1)—C(11) | 1.333(12) | C(17)—Pt(2)—N(4) | 174.0(4) |
| N(1)—C(7) | 1.370(12) | N(3)—Pt(2)—N(4) | 95.1(5) |
| N(2)—C(12) | 1.309(12) | C(17)—Pt(2)—S(2) | 95.2(4) |
| N(2)—C(16) | 1.376(11) | N(3)—Pt(2)—S(2) | 171.3(3) |
| N(3)—C(27) | 1.342(15) | N(4)—Pt(2)—S(2) | 89.3(2) |
| N(3)—C(23) | 1.373(17) | C(17)—Pt(2)—Pt(1) | 99.5(3) |
| N(4)—C(32) | 1.340(11) | N(3)—Pt(2)—Pt(1) | 101.6(3) |
| N(4)—C(28) | 1.375(12) | N(4)—Pt(2)—Pt(1) | 84.9(2) |
| C(1)—C(2) | 1.396(13) | S(2)—Pt(2)—Pt(1) | 86.24(7) |
| C(1)—C(6) | 1.399(13) | C(32)—S(1)—Pt(1) | 109.3(4) |
| C(2)—C(3) | 1.373(14) | C(16)—S(2)—Pt(2) | 110.6(3) |
| C(2)—H(2A) | 0.9300 | C(27)—N(3)—Pt(2) | 125.4(11) |
| C(11)—N(1)—Pt(1) | 125.0(8) | C(23)—N(3)—Pt(2) | 116.7(12) |
| C(7)—N(1)—Pt(1) | 113.7(7) | C(32)—N(4)—C(28) | 118.6(10) |
| C(16)—N(2)—Pt(1) | 125.0(6) | C(32)—N(4)—Pt(2) | 125.7(7) |
| C(27)—N(3)—C(23) | 117.9(14) | | |

While the invention has been described by way of example and in terms of preferred embodiment, it is to be understood that the invention is not limited thereto. It is therefore intended that the following claims be interpreted as covering all such alteration and modifications as fall within the true spirit and scope of the invention.

What is claimed is:

1. An organometallic compound having a formula (I), of: 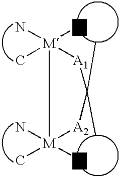
wherein
M and M′ are each independently transition metals;
R is a heterocyclic group including at least one nitride atom;
A₁ and A₂ are each independently a sulfur, oxygen, or nitride atom; and 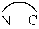
are independently a bidentate ligand comprising a nitride atom and a carbon atom bonded to M or M′.

2. The organometallic compound as claimed in claim 1, wherein M and M′ are the same.

3. The organometallic compound as claimed in claim 1, wherein A₁ and A₂ are the same.

4. The organometallic compound as claimed in claim 1, wherein M and M′ are transition metals with molecular weight more than 40.

5. The organometallic compound as claimed in claim 1, wherein M and M′ are Ir, Os, Pt, Pb, Re, or Ru.

6. The organometallic compound as claimed in claim 1, wherein 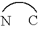
are independently 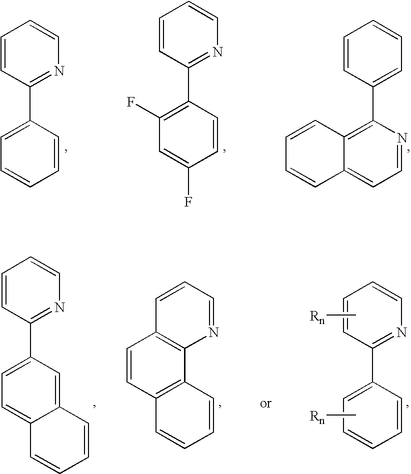
wherein Rₙ is hydrogen, alkyl, alkenyl, alkynyl, CN, CF₃, alkylamino, amino, alkoxy, halo, aryl, or heteroaryl.

7. The organometallic compound as claimed in claim 1, wherein at least one hydrogen atom bonded to the carbon atom of 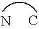
is substituted optionally by an electron donating or electron withdrawing group.

8. he organometallic compound as claimed in claim 1, wherein at least one hydrogen atom bonded to the carbon atom of 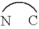
is substituted optionally by alkyl, alkenyl, alkynyl, CN, CF₃, alkylamino, amino, alkoxy, halo, aryl, or heteroaryl.

9. The organometallic compound as claimed in claim 1,

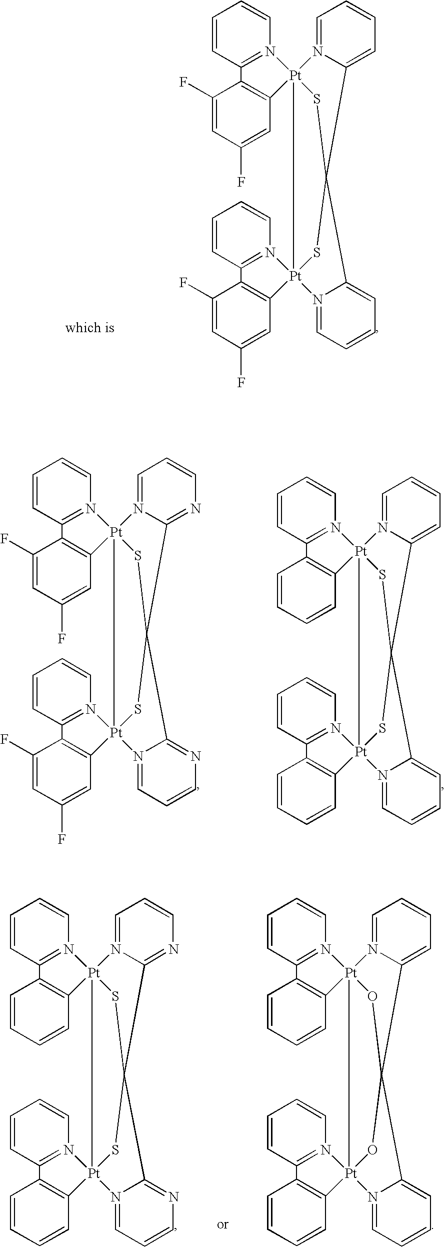

10. The organometallic compound as claimed in claim 1, wherein the organometallic compound serves as an emitting layer material of an electroluminescent display device.

11. The organometallic compound as claimed in claim 1, wherein the organometallic compound emits light in the orange or red spectrum.

12. A display device, comprising:
a substrate;
an anode formed on the substrate;
organic electroluminescent layers formed on the anode; and
a cathode formed on the organic electroluminescent layers,
wherein,
the organic electroluminescent layers comprise an organometallic compound having a formula (I), of: 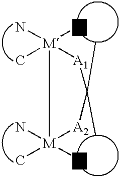
wherein
M and M′ are each independently transition metals;
R is a heterocyclic group including at least one nitride atom;
A₁ and A₂ are each independently a sulfur, oxygen, or nitride atom; and 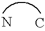
are independently a bidentate ligand comprising a nitride atom and a carbon atom bonded to M or M′.

13. The display device as claimed in claim 12, wherein M and M′ are the same.

14. The display device as claimed in claim 12, wherein A₁ and A₂ are the same.

15. The display device as claimed in claim 12, wherein M and M′ are transition metals with molecular weight more than 40.

16. The display device as claimed in claim 12, wherein M and M′ are Ir, Os, Pt, Pb, Re, or Ru.

17. The display device as claimed in claim 12, wherein 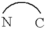
are independently 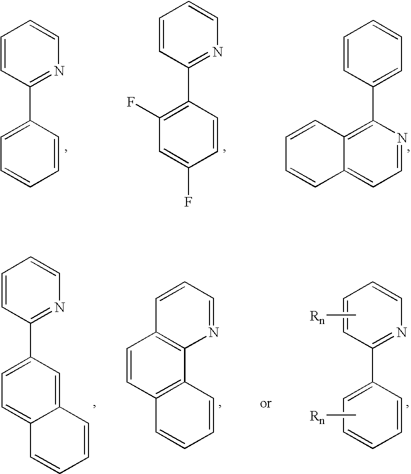
wherein Rₙ is hydrogen, alkyl, alkenyl, alkynyl, CN, CF₃, alkylamino, amino, alkoxy, halo, aryl, or heteroaryl.

18. The display device as claimed in claim 12, wherein at least one hydrogen atom bonded to the carbon atom of 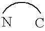
is substituted optionally by an electron donating or electron withdrawing group.

19. The display device as claimed in claim 12, wherein at least one hydrogen atom bonded to the carbon atom of 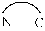
is substituted optionally by alkyl, alkenyl, alkynyl, CN, CF₃, alkylamino, amino, alkoxy, halo, aryl, or heteroaryl.

20. The display device as claimed in claim 12, wherein the organometallic compound is

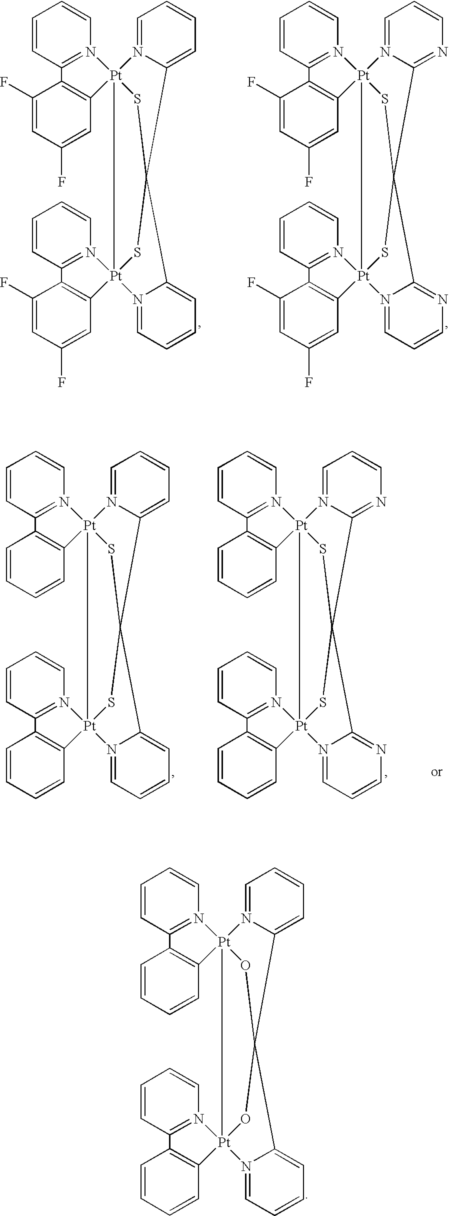

21. The display device as claimed in claim 12, wherein the organometallic compound serves as an emitting layer material of an electroluminescent display device.

22. The display device as claimed in claim 12, wherein the organometallic compound emits light in the orange or red spectrum.
